(19) United States
(12) Patent Application Publication
(10) Pub. No.: US 2006/0221209 A1
(43) Pub. Date: Oct. 5, 2006

(54) Apparatus and method for acquiring and combining images of a scene with multiple optical characteristics at multiple resolutions

(76) Inventors: Morgan McGuire, Sunnyvale, CA (US); Wojciech Matusik, Cambridge, MA (US); Hanspeter Pfister, Arlington, MA (US)

Correspondence Address: Patent Department;Mitsubishi Electric Research Laboratories, Inc., 201 Broadway, Cambridge, MA, 02139, US

(21) Appl. No.: 11/092,375

(22) Filed: Mar. 29, 2005

(51) Int. Cl. H01L 27/00; H04N 5/262; G06K 9/32

(52) U.S. Cl. 348/239; 382/294

(57) ABSTRACT

A camera system acquires multiple optical characteristics at multiple resolutions of a scene. The camera system includes multiple optical elements arranged as a tree having a multiple of nodes connected by edges. the nodes represent optical elements sharing a single optical center, and the edges representing light paths between the nodes. The tree has the following structure: a single root node acquiring a plenoptic field originating from a scene; nodes with a single child node represent filters, lenses, apertures, and shutters; nodes with multiple child nodes represent beam splitters and leaf nodes represent imaging sensors. Furthermore, a length of the light paths from the roof node to each leaf nodes can be equal.

### RELATED APPLICATION

This U.S. Patent Application is related to U.S. patent application Ser. No. 11/______, titled “System and Method for Image Matting,” by McGuire, et al., co-filed herewith.

### FIELD OF THE INVENTION

This invention relates generally to cameras, and more particularly to a camera system that acquires and combines multiple optical characteristics at multiple resolutions of a scene into a single image.

### BACKGROUND OF THE INVENTION

In the context of computer vision, multiple images of a scene, where the images are geometrically similar but radiometrically different, are useful for many applications, such as high dynamic range (HDR) imaging, focus and defocus analysis, multi-spectral imaging, high speed videography and high spatial resolution imaging.

Beam splitting is commonly used to acquire multiple reduced amplitude images of a plenoptic light field in a scene. With beam splitting the different images can be acquired concurrently.

Acquiring concurrently multiple images is difficult. First, one must ensure that optical paths to imaging sensors are geometrically similar. This is difficult because all the optical elements have six degrees of orientation freedom, three for translation, and three for rotation. Therefore, the optical elements must be located precisely. Second, the optical elements are subject to manufacturing aberrations that distort the plenoptic function away from the ideal.

Acquiring multiple images has been performed for various applications, however, rarely, more than three images are acquired, such as in color imaging.

Beam Splitters

Prisms and half-silvered mirrors are common beam splitters used to direct a light field along multiple paths. Typically, a ratio of intensities of the light field directed to each path at each wavelength can be adjusted. Beam splitter can be placed between the scene and the lens, or between the lens and the imaging sensors.

When imaging sensors are arranged immediately against sides of a splitting prism, the sensors are automatically registered up to a 2D translation. In the case of 3D-CCD cameras, a dichroic prism is often used to acquire three images, each representing a different spectral band.

Prisms have also been used for HDR imaging, U.S. Pat. No. 5,801,773, “Image data processing apparatus for processing combined image signals in order to extend dynamic range,” issued to Ikeda on September 1998.

Alternative the light field can be split between the lens and the sensor, Shree K. Nayar, Masahiro Watanabe and Minori Noguchi, “Real-Time Focus Range Sensor”, IEEE Trans. Pattern Anal. Mach. Intell., vol. 18, n. 12, pp. 1186-1198, 1996. That alternative shares a single lens for all sensors, which simplifies lens calibration and reduces lens cost, while making calibration and filter changes more difficult.

Pyramid Mirrors

Another system acquires multiple images by placing a pyramid mirror between the lens and the sensors to produce compact optical paths, U.S. Pat. No. 5,734,507, “Optical beam splitter and electronic high speed camera incorporating such a beam splitter,” issued to P. Harvey in 1998, and M. Aggarwal and N. Ahuja, “Split Aperture Imagingfor High Dynamic Range,” IJCV, vol. 58, n. 1, pp. 7-17, June 2004.

However, that system requires a large aperture, which leads to a narrow depth of field and limits the applications for which the system can be used. In fact, it is impossible to duplicate a pinhole view with using a pyramid mirror. It is also non-trivial to distribute the light intensity evenly to all four sensors, which is desired for HDR images. Furthermore, the edges of the pyramid cause radiometric falloffs. Even when the system is calibrated, this reduces the effective dynamic range of each image. Furthermore, when the pyramid mirror is placed behind the lens, the point spread functions is wedge-shaped instead of disk-shaped because each sensor's effective aperture is a wedge. This makes it difficult to fuse or otherwise compare images in which some objects are out of focus, or where the multiple images are acquired at different depths of focus. Objects outside the depth of field appear defocused, and the objects are shifted away from their true positions.

Other Alternatives

For scenes that are at infinity, there is no parallax and the optical centers of the sensors need not be aligned as long as the optical axes are parallel. In this case, view dependent effects and occlusions are not a problem. In practice, the parallax error is tolerable for scenes as near as ten meters, provided the depth range of the scene is relatively small.

In this case, stereo or other dense arrays of sensor can be used to obtain the multiple images of the scene, as if the images were acquired from the same viewpoint, Y. Goto, K. Matsuzaki, I. Kweon and T. Obatake, “CMU sidewalk navigation system: a blackboard-based outdoor navigation system using sensorfusion with colored-range images,” Proceedings of 1986 fall joint computer conference on Fall joint computer conference, pp. 105-113. IEEE Computer Society Press, 1986, and Bennett Wilburn, Neel Joshi, Vaibhav Vaish, Marc Levoy and Mark Horowitz, “High speed video using a dense camera array,” Proceedings of CVPR04, June 2004.

Compared to a camera system with beam splitters, each sensors in the dense array acquires the full complement of light intensity. However, a beam splitter system can operate over a larger depth range, and can offer the possibility of sharing expensive optical components, such as filters for the multiple sensors.

Another technique uses a mosaic of sensors to sample multiple parameters in a single image. A conventional classic Bayer mosaic tiles single-pixel band-pass filters over a sensor. The sensors can acquire light at three wavelengths with a single monochrome sensor.

Filtered optical systems for acquiring other optical characteristics with high precision are also known, S. K. Nayar and T. Mitsunaga, “High Dynamic Range Imaging: Spatially Varying Pixel Exposures,” CVPR00, pp. I: 472-479, 2000, and S. K. Nayar and S. G. Narasimhan, “Assorted Pixels: Multi-sampled Imaging with Structural Models,” ECCV02, page IV: 636 ff., 2002. Those systems are compacts, and do not require any calibration during operation. However, increasing the intensity resolution is done at the expense of reducing the spatial resolution, which is not desirable for some applications. It is also difficult to manipulate concurrently the aperture, spatial and temporal resolutions with such a system.

Therefore, it is desired to provide a camera system that can acquire and combine images and videos expressing multiple optical characteristics of a scene at multiple resolutions.

### SUMMARY OF THE INVENTION

Beam splitting is commonly used for acquiring multiple geometrically similar but radiometrically controlled images of a scene. However, acquiring a large number of such images is known to be a hard problem.

The invention provides a camera system where optical elements, such as filters, mirrors, apertures, shutters, beam splitters, and sensors, are arranged physically as a tree. The optical elements recursively split a monocular plenoptic field of a scene a large number of times.

Varying the optical elements enables the invention to acquire, at each virtual pixel, multiple samples that vary not only in wavelength but also vary for other optical characteristics, such as focus, aperture, polarization, subpixel position, and frame time.

The camera system according to the invention can be used for a number of application, such as HDR, multi-focus, high-speed, and hybrid high-speed multi-spectral imaging.

### BRIEF DESCRIPTION OF THE DRAWINGS

FIG. 1 is a schematic of a monocular camera system having optical elopements arranged as a balanced tree according to the invention;

FIG. 2 is a top view of a camera system according to the invention, which is represented as a full binary tree;

FIG. 3 is an alternative arrangement of optical elements according to the invention;

FIG. 4 is an arrangement of optical elements in an unbalanced tree according to the invention; and

FIG. 5 is an arrangement of optical elements for a multi-modal camera system according to the invention.

### DETAILED DESCRIPTION OF THE PREFERRED EMBODIMENT

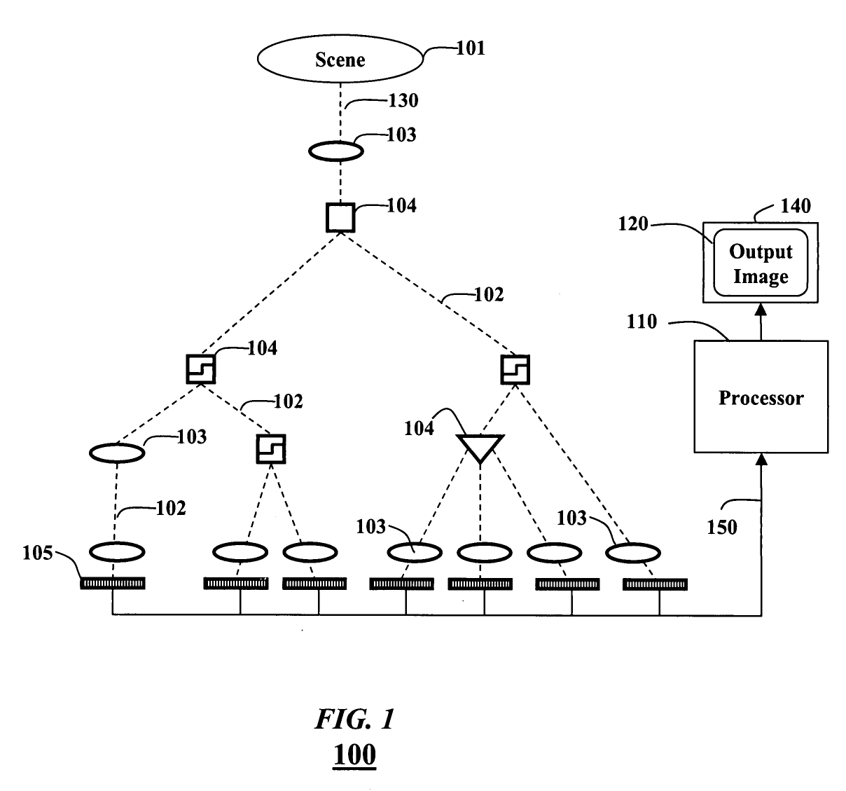

FIG. 1 is a camera system 100 according to our invention. The camera system can acquire and combine multiple optical characteristics at multiple resolutions of a scene 101 into a single output image 120. The camera system 100 can also acquire multiple sequences of frames, and produce a single output video that combines the multiple characteristics at the multiple resolutions.

Abstractly, our camera system 100 is in a form of an optical splitting trees including nodes connected by edges 102. The edges of the tree represent light paths, and the nodes are optical elements, e.g., filters, lenses, mirrors, apertures, shutters, and imaging sensors.

Nodes 103 with a single child node represent optical filters, lenses, apertures, and shutters. Nodes 104 with multiple children are beam splitters, and tilt mirrors. If the beam splitter is a half-mirror, then the node has a branching factor of two.

Other splitting elements, prism, pyramids and tilt mirrors, can produce branching factors of a higher degree. Leaf nodes 105 are imaging sensors. The imaging sensors 105 is coupled to a processor 110 configured to perform a method according to the invention to produce a single combined output image or video 120 of the scene 101 on a display unit 140.

A plenoptic field 130 originating from the scene 101 enters the camera system 100 at the root of the tree. A physical length of each light path from the center of the root node to the center of each sensor can be identical. In that instance, because we know that all paths from the root to the leaves have the same physical length, the representation shown in the Figures need not preserve distances, where distances are preserved when all the paths from the root to the leaves do not have the same physical length. However, a depth of the tree, in terms of the number of internal nodes along the equal-length light paths can differ.

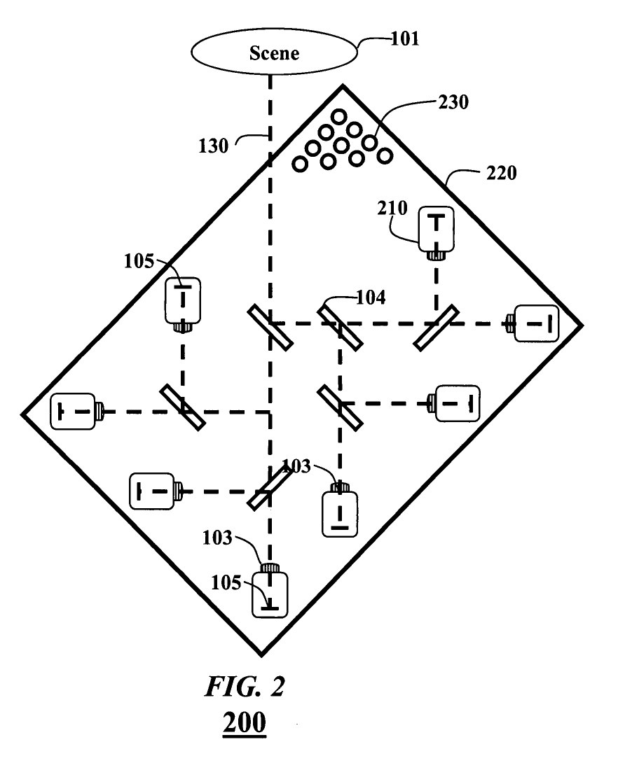

FIG. 2 shows a camera system 200 according to invention configured as a full binary splitting tree, viewed from above. This configuration is designed to compact the optical elements into a small form factor without occluding any optical path. By building the tree at 45° angle relative to the plenoptic field, we make efficient use of space. Here, the beam splitters 104 are arranged between the scene 101 and the lenses immediately 103 in front of the imaging sensors 105. Thus, we can adjust the depth of focus, aperture, and time exposure independently for each light path 102.

Angles are an artifact of building the physical camera system, and need not be represented. Thus, we are left with an abstraction where only a topology of the graph, i.e., the tree, is of significance.

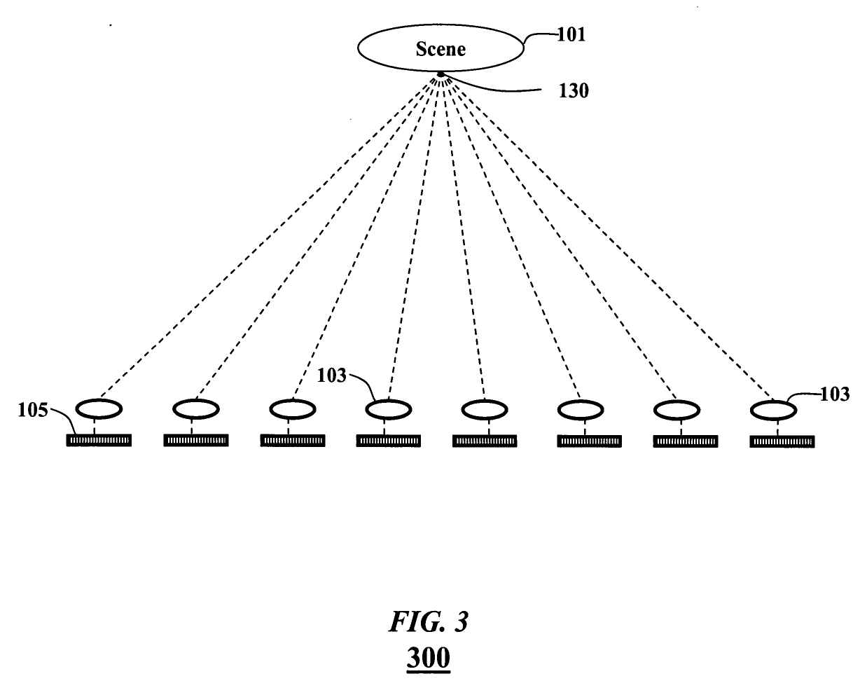

As shown in the configuration 300 of FIG. 3, when internal nodes serve only to produce copies of an image and do not filter the view, we can collapse their representation into a single node with many children. This representation also abstracts the nature of the of splitting element that is being employed. This configuration can be used for multi-spectral imaging if each lens 103 is a band-pass filters. Each light path receives about ⅛^{th} of the incident light field, which is band-pass filtered immediately before the corresponding sensors 105.

For some applications, it is desirable to construct a balanced binary tree, in which all the sensor are at the same tree depth, and the beam splitters partition the incident light evenly between their child nodes.

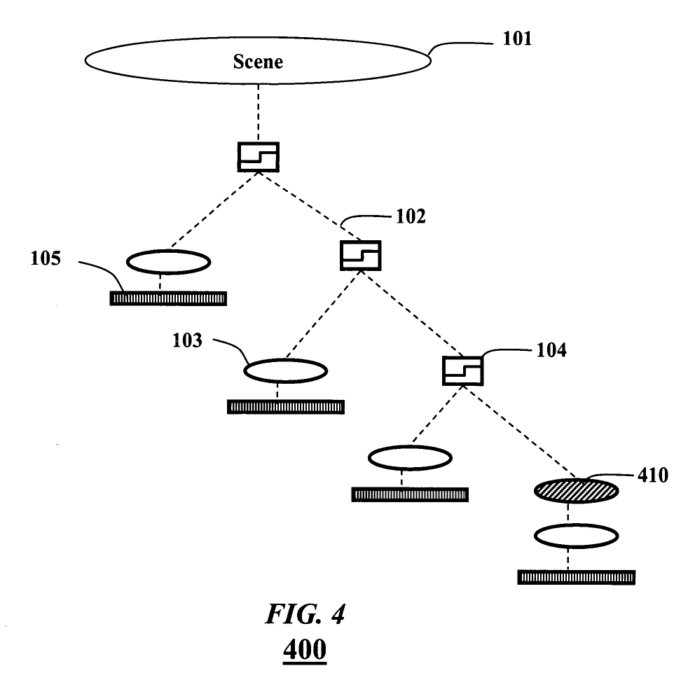

In other applications it is useful to unbalance the tree, see FIG. 4. We can do so either by using beam splitters with an uneven division ratio, or by constructing a structurally unbalanced tree, where the tree-depths of the sensors vary, see the description of a high dynamic range (HDR) camera according to the invention below.

The underlying object of the invention is to sample the plenoptic field at multiple optical characteristics and multiple resolutions. This is true regardless of the specific configuration of the optical elements in the tree. There are many parameters along which one can sample. In the case of subpixel rotations, we achieve a high spatial resolution. When color filters are used, the wavelength sampling resolution is increased. Other trees increase the luminance, temporal, complex phase, and polarization resolutions.

Camera System

We construct the example camera system 200 of FIG. 2 with eight hardware synchronized cameras 210 and a reconfigurable full-balanced optical splitting tree using half-mirrors. We use Basle A601fc Bayer filter color cameras, and Basle A601f monochrome cameras with 640×480 resolution. Each camera is equipped with a 50 mm lens 105 for a narrow field of view that allows us to use relatively small beam splitters 104. For a splitting tree with a depth of three, i.e., 2³ or eight sensors, the largest beam splitter is about 100×100 mm², and the smallest beam splitter is about 75×75 mm². All optical elements are mounted on a 2′×3′ optical breadboard 220 with mounting holes 230 spaced apart by ½″ arranged in a rectangular grid.

The cameras 210 are connected to a 3 GHz Pentium 4 processor 110 using a FireWire interface 150. An LCD display 140 connected to the processor 110 outputs the individual images or video streams for rapid feedback during video acquisition. A hardware trigger synchronizes the timing of the cameras.

Calibration

The difficulty of calibrating a camera system increases with the number of optical elements. Multiple sensors that share an optical center are more difficult to calibrate, than a camera system that uses a stereo pair of sensors, because images are not expected to align. We calibrate our camera system in three stages. First, we align the beam splitters. Second, we align the sensors. Third, we determine homographies to correct any remaining misregistration with software manipulation of the acquired images.

Rotations of the sensors relative to the optical paths can be perfectly corrected by the homography, up to a sampling precision. The optical paths 102 between the lens and sensors are relatively short compared to depths in the scene 101. Therefore, the exact positions of the sensor on the optical paths is not critical.

A primary concern for calibration of the optical elements is translation of the sensors perpendicular to the optical axis. The translation produces parallax that cannot be corrected in software. If we use half-mirrors for beam splitting, then the mirrors are rotated at 45° with respect to the optical axis.

To calibrate the half-mirrors, we place a cap in front of each lens 105. We aim a laser beam at the beam splitter at the root node of our tree. This produces a single dot at the center of lens cap. Working through the splitting tree from the root node to the leaves nodes, we adjust the beam splitters until each dot appears at the center of the lens cap.

Then, we construct a scene containing a foreground target, e.g., five bulls eyes, printed on transparent plastic as a foreground element and a enlarged background target printed on a poster board. We move the foreground target until its pattern exactly overlaps the background target in the view of a first sensor. Then, we translate all other sensors until the target patterns also overlap in their views, adjusting the pose of the sensors as needed.

Finally, we determine a homography matrix for each sensor to map its view to the view of the first sensor. The homography matrix is determined from corresponding points that are either selected manually or automatically by imaging the movement of a small LED light throughout the scene. The automatic method is convenient in cases where it is hard to visually select corresponding points, such as when the sensors are focused at different depths, or receive different amounts of light, as for HDR imaging.

We determine an affine matrix by solving a least squares problem given the corresponding points. It is also possible to determine an arbitrary deformation from the corresponding points to account for lens aberration.

Changing filters, focusing, adjusting apertures does not affect the branch structure of the tree substantially.

Applications

The camera system according to the invention can be used in a number of different applications.

High Dynamic Range Imaging

Acquiring images with a high dynamic range (HDR) is an important in computer vision and computer graphics to deal with a huge variance of radiance in most natural scenes. A number of techniques are known that either vary exposure settings or use a mosaic of filters, Sing Bing Kang, Matthew Uyttendaele, SimonWinder and Richard Szeliski, “High dynamic range video,” ACM Trans. Graph., vol. 22, n. 3, pp. 319-325, 2003, Paul E. Debevec and Jitendra Malik, “Recovering high dynamic range radiance maps from photographs,” Proceedings of the 24th annual conference on Computer graphics and interactive techniques, pp. 369-378. ACM Press/Addison-Wesley Publishing Co., 1997, T. Mitsunaga and S. Nayar, “Radiometric Self Calibration,” in IEEE Computer Society Conference on Computer Vision and Pattern Recognition, volume 1, pp. 374-380, 1999, and T. Mitsunaga and S. Nayar, “High dynamic range imaging: Spatially varying pixel exposures,” IEEE Computer Society Conference on Computer Vision and Pattern Recognition, volume 1, pp. 472-479, 2000.

Using an optical splitting tree according to the invention has a number of advantages for HDR imaging. The amount of motion blur and the point spread function in each image are constant. Very little light is discarded when an unbalanced tree of beam splitters is used.

FIG. 4 is our camera system 400 configured for acquired HDR images using four sensors 105. Each beam splitter 104 directs half the light to each of its child nodes. The left sub-tree always terminates at a sensor 105. The right sub-tree recurses. Before the right-most sensor, we insert a single neutral-density 50% filter 410. Because the sensors have 10-bits of precision internally, and only an 8-bits of output, we shift the gain by a factor of four from the brightest to the dimmest sensor. Thus, the theoretical dynamic range is 8192:1 for sensors that measure linear radiance. In practice, we also vary our exposure time and apertures slightly to obtain a ratio of about 20000:1.

For HDR imaging, intensity and color calibration are not as important as spatial and temporal calibration because intensities are adjusted and merged with a conventional tone mapping process. The intensity difference between sensors can be inferred from a sequence of images with overlapping unsaturated pixels.

Multiple Focus and Defocus Imaging.

In this application, images are acquired with depths of field to recover depth information of the scene, and to form images with an infinite or discontinuous depth of fields.

Some prior art camera systems e.g., Shree et al. above, split the light field between the lens and the sensors. In contrast, we split the light field between the scene and the lens. This enables us to vary the location of the focal plane and the depth of the field by changing the aperture of the lens. Thus, we can use a ‘pinhole’ camera, with an infinite depth of field, as well as a narrow depth of field camera, for a matting application, see the related U.S. patent application Ser. No. 11/______, titled “System and Method for Image Matting,” by McGuire, et al., co-filed herewith and incorporated herein by reference.

High Speed Imaging

Some camera systems can acquire frames at over 2000 f.p.s. For example, one prior art high speed camera system uses a closely spaced linear array of 64 cameras, see Wilburn et al. above.

In contrast, the sensors in our camera system share a single optical center. Thus, our camera system acquires accurately view-dependent effects, and do not suffer from occlusions due to different points of view as in the prior art camera system. There are other benefits of our a high-speed camera system using optical splitting trees. Because the multiple frames are captured by different sensors, the exposure time and frame rate are not linked, that is, the exposure time and frame rate can be independent of each other, unlike conventional cameras.

With eight cameras operating at 30 f.p.s, we can acquire a video with an effective frame rate of 240 f.p.s, with a relatively long exposure time, e.g., 1/30 of a second. Thus, smooth movement can be observed with motion blur.

Even when it is desirable to keep the frame rate and exposure time constant, the exposure of a single-sensor high speed camera only asymptotically approaches the desired frame rate, because it takes time to discharge and measure the sensors. Furthermore, the data rate from a single sensor high speed camera is enormous, which presents problems at the output of the sensor.

However, our multi-sensor camera system can discharge one sensor while acquiring a next image with another sensor, and a separate relatively low data communications link can be used for each sensor. Multiple sensors also enable parallel processing. With multiple sensors and multiple filters, it is also possible to acquire a combined high-speed and multi-spectral video.

Multimodal Camera System

Prior art camera systems are generally designed to increase the sampling resolution of a particular optical characteristic, e.g., wavelength, as in a RGB color camera.

In contrast, the camera system according to the invention can concurrently manipulate the resolutions of multiple optical characteristics. The high-dimensional camera system according to the invention can concurrently trade different resolution of different optical characteristics by arranging optical elements, such as filters, lenses, apertures, shutters, beam-splitters, tilting mirrors, and sensors as a hybrid tree. Such as hybrid camera system is more effective than a conventional camera era system that undersamples all other optical characteristics in order to acquire only one optical characteristic at a higher resolution.

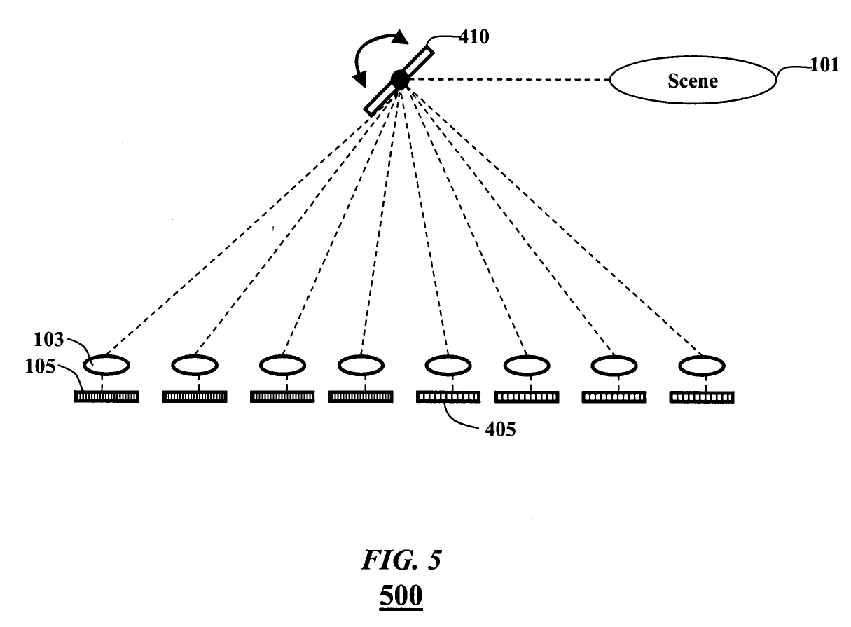

FIG. 5 shows a high speed camera system 500 that acquires images at visible and infrared wavelengths. The system includes a tilt mirror 410, visible light sensors 105, and infrared sensors 405. The sensors can be arranged linearly, or as an array.

It should be noted, that other optical characteristics can also be considered for this configuration, by including additional optical elements between the scene and sensors.

Effect of the Invention

The invention provides a camera system arranged as a tree for monocular imaging. The system can concurrently acquire images or videos of multiple optical characteristics and at multiple resolutions.

With the camera system according to the invention, applications, such as HDR, high-speed, multi-spectral, and multi-focus imaging become much easier and result in better quality output images compared to prior art solutions.

Although the invention has been described by way of examples of preferred embodiments, it is to be understood that various other adaptations and modifications may be made within the spirit and scope of the invention. Therefore, it is the object of the appended claims to cover all such variations and modifications as come within the true spirit and scope of the invention.

We claim:

1. A camera system for acquiring multiple optical characteristics at multiple resolutions of a scene, comprising:
a plurality of optical elements arranged as a tree having a plurality of nodes connected by edges, the nodes representing optical elements sharing a single optical center, and the edges representing light paths between the nodes, the tree further comprising:
a single root node;
nodes with a single child node representing filters, lenses, apertures, and shutters; and
node with multiple child nodes representing beam splitters; and
leaf nodes representing imaging sensors.

2. The camera system of claim 1, in which a total length of each light path from the root node to each leaf node is equal.

3. The camera system of claim 1, in which a total length of each light path from the root node to each leaf node is different.

4. The camera system of claim 1, in which the imaging sensors acquire synchronously a set of images, and the set of images are combined into a single output image.

5. The camera system of claim 1, in which the imaging sensors acquire synchronously a set of video, and the set of videos are combined into a single output video.

6. The camera system of claim 1, in which the imaging sensors acquire concurrently images at a plurality of resolutions of a plurality of optical characteristics.

7. The camera system of claim 6, in which the plurality of resolutions include spatial resolutions, and temporal resolutions.

8. The camera system of claim 1, in which the imaging sensors acquire synchronously a set of images of a scene, and the set of images are combined into a single output image representing multiple optical characteristics at multiple resolutions of the scene.

9. The camera system of claim 1, in which a plenoptic field originating from a scene enters the camera system at the root of the tree.

10. The camera system of claim 1, in which a depth of the tree, in terms of a number of internal nodes along the light paths from the root node to the leaf nodes is different for different light paths.

11. The camera system of claim 6, in which the plurality of resolutions include depth of focus resolutions.

12. The camera system of claim 6, in which the plurality of resolutions include aperture resolutions.

13. The camera system of claim 1, in which the tree is balanced.

14. The camera system of claim 1, in which the tree is unbalanced.

15. The camera system of claim 1, in which the plurality of resolutions include wavelength resolutions.

16. The camera system of claim 1, in which the plurality of luminance resolutions.

17. The camera system of claim 1, in which the plurality of resolutions include complex phase resolutions.

18. The camera system of claim 1, in which the plurality of resolutions include polarization resolutions.

19. The camera system of claim 1, in which the plurality of resolutions include wavelength resolutions and depth of focus resolutions.

20. The camera system of claim 4, in which the output image is a high dynamic range image.

21. The camera system of claim 5, in which an exposure time and a frame rate for the plurality of videos are independent of each other.

22. The camera system of claim 4, in which the set of images are processed in parallel.

23. The camera system of claim 4, in which the output video combines high-speed and multi-spectral videos.

24. The camera system of claim 1, in which the imaging sensors acquire synchronously a set of images at visible wavelengths and infrared wavelengths.
